(19) United States
(12) Patent Application Publication
(10) Pub. No.: US 2026/0215278 A1
(43) Pub. Date: Jul. 23, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Seunghyun Ko, Suwon-si (KR); Byounggug Min, Suwon-si (KR)

(21) Appl. No.: 19/378,032

(22) Filed: Nov. 3, 2025

(30) Foreign Application Priority Data
Jan. 22, 2025 (KR) 10-2025-0009680

(51) Int. Cl. H10W 42/00; H10W 42/20; H10W 74/10; H10W 90/00

(52) U.S. Cl. CPC H10W 42/121; H10W 42/20; H10W 74/117; H10W 90/701; H10W 90/724; H10W 90/754

(57) ABSTRACT

A semiconductor package includes a package substrate, a semiconductor chip, a molding member, a bending prevention structure and an electromagnetic-wave shielding structure. The semiconductor chip is disposed on the package substrate. The molding member is disposed on the package substrate and covers the semiconductor chip. The bending prevention structure is disposed on an upper surface of the molding member, and includes bending prevention patterns stacked in a vertical direction substantially perpendicular to an upper surface of the package substrate. The electromagnetic-wave shielding structure is disposed on an upper surface and a sidewall of the bending prevention structure, a sidewall of the molding member and a sidewall of the package substrate.

### CROSS-REFERENCE TO RELATED APPLICATION

This application claims priority under 35 U.S.C. § 119 to Korean Patent Application No. 10-2025-0009680, filed on January 22, 2025 in the Korean Intellectual Property Office (KIPO), the contents of which are herein incorporated by reference in their entirety.

### TECHNICAL FIELD

The present disclosure relates to a semiconductor package and a method of manufacturing the same.

### BACKGROUND

A semiconductor package includes a package substrate, a semiconductor chip on the package substrate, a bonding wire for electrically connecting the package substrate and the semiconductor chip, and a molding member disposed on the package substrate and covering the semiconductor chip and the bonding wire. A method of shielding the semiconductor package from external electromagnetic-waves and protecting the semiconductor package from external impact is needed.

### SUMMARY

Example embodiments provide a semiconductor package having enhanced bending strength and enhanced electromagnetic shielding and hence, enhanced electrical characteristics.

Example embodiments provide a method of manufacturing a semiconductor package having enhanced bending strength and enhanced electromagnetic shielding and hence, enhanced electrical characteristics.

According to example implementations, there is provided a semiconductor package. The semiconductor package may include a package substrate, a semiconductor chip, a molding member, a bending prevention structure and an electromagnetic-wave shielding structure. The semiconductor chip may be on the package substrate. The molding member may be on the package substrate and cover the semiconductor chip. The bending prevention structure may be on an upper surface of the molding member, and may include bending prevention patterns stacked in a vertical direction substantially perpendicular to an upper surface of the package substrate. The electromagnetic-wave shielding structure may be on an upper surface and a sidewall of the bending prevention structure, a sidewall of the molding member and a sidewall of the package substrate.

According to example implementations, there is provided a semiconductor package. The semiconductor package may include a package substrate, a semiconductor chip, a molding member, a bending prevention structure and an electromagnetic-wave shielding structure. The semiconductor chip may be on the package substrate. The molding member may be on the package substrate and covering the semiconductor chip. The bending prevention structure may be on an upper surface of the molding member, and may include first and second bending prevention patterns alternately stacked in a vertical direction substantially perpendicular to an upper surface of the package substrate. The electromagnetic-wave shielding structure may be on an upper surface and a sidewall of the bending prevention structure, a sidewall of the molding member and a sidewall of the package substrate. The first bending prevention pattern may include a first conductive material having a first electrical conductivity, and the second bending prevention pattern may include a second conductive material having a second electrical conductivity greater than the first electrical conductivity.

According to example implementations, there is provided a semiconductor package. The semiconductor package may include a package substrate, a semiconductor chip, a bonding wire, a molding member, a bending prevention structure, an electromagnetic-wave shielding structure and an external connection pad. The semiconductor chip may be on the package substrate. The bonding wire may electrically connect the package substrate and the semiconductor chip. The molding member may be on the package substrate and cover the semiconductor chip and the bonding wire. The bending prevention structure may be on an upper surface of the molding member, and may include first and second bending prevention patterns alternately stacked in a vertical direction substantially perpendicular to an upper surface of the package substrate. The electromagnetic-wave shielding structure may be on an upper surface and a sidewall of the bending prevention structure, a sidewall of the molding member and a sidewall of the package substrate. The electromagnetic-wave shielding structure may include an adhesion layer, a shielding layer and an anti-oxidation layer sequentially stacked. The external connection pad may be on a lower surface of the package substrate.

According to example implementations, there is provided a method of manufacturing a semiconductor package. In the method, a semiconductor chip may be on a package substrate. A molding member may be formed on the package substrate to cover the semiconductor chip. A bending prevention layer structure may be formed on the molding member. A sawing process may be performed on the package substrate and the molding member to form preliminary semiconductor packages. An electromagnetic-wave shielding structure may be formed on an upper surface and a sidewall of each of the preliminary semiconductor packages.

In example implementations, when the bending prevention layer structure is formed on the molding member, first and second bending prevention layers may be alternately stacked on the molding member.

In example implementations, the first and second bending prevention layers may include first and second conductive materials, respectively, which are different from each other.

In example implementations, the first conductive material may have a first electrical conductivity, and the second conductive material may have a second electrical conductivity.

In example implementations, the first conductive material may include stainless steel or titanium, and the second conductive material may include gold, silver or copper.

In example implementations, the first bending prevention layer and the second bending prevention layer may have different thicknesses from each other.

In example implementations, when the electromagnetic-wave shielding structure is formed, an adhesion layer, a shielding layer and an anti-oxidation layer may be sequentially stacked on the upper surface and the sidewall of each of the preliminary semiconductor packages.

In example implementations, each of the adhesion layer and the anti-oxidation layer may include a first conductive material, and the shielding layer may include a second conductive material.

In example implementations, the first conductive material may include stainless steel or titanium, and the second conductive material may include gold, silver or copper.

In example implementations, the adhesion layer and the anti-oxidation layer may have the same thickness, and the shielding layer may have a thickness different from a thickness of the adhesion layer or the anti-oxidation layer.

The semiconductor package in accordance with example implementations may include the bending prevention structure on the molding member, and the bending prevention structure may include a plurality of bending prevention patterns. Thus, the bending prevention structure may have improved stiffness, and may hinder the semiconductor package from bending effectively.

### BRIEF DESCRIPTION OF THE DRAWINGS

FIG. 1 is a cross-sectional view illustrating a semiconductor package in accordance with example implementations.

FIGS. 2 to 4 are cross-sectional views illustrating a method of manufacturing a semiconductor package in accordance with example implementations.

FIG. 5 is a cross-sectional view illustrating a semiconductor package in accordance with example implementations.

### DETAILED DESCRIPTION

Hereinafter, example implementations will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

A direction parallel to an upper surface or a lower surface of a package substrate may be referred to as a horizontal direction, and a direction perpendicular to the upper surface or the lower surface of the package substrate may be referred to as a vertical direction.

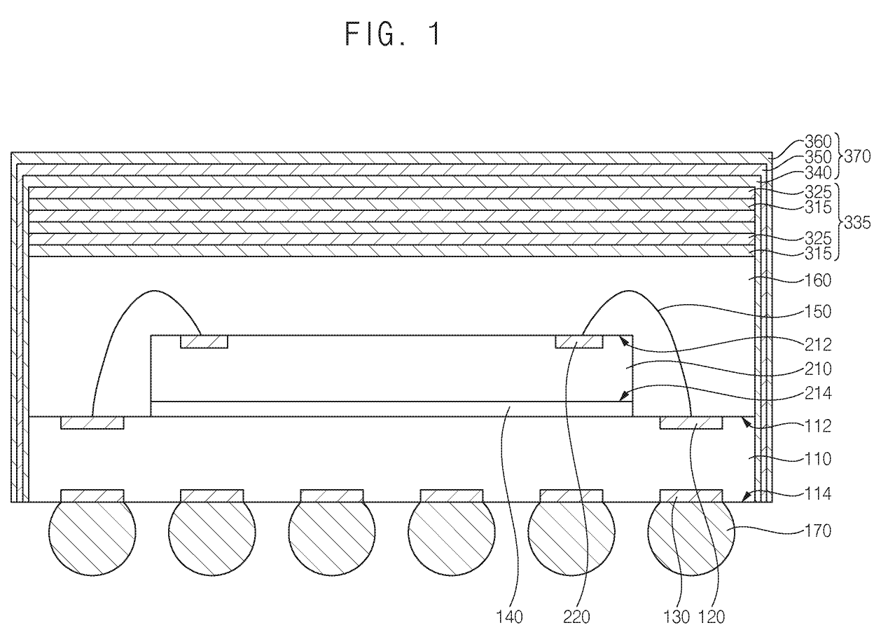

FIG. 1 is a cross-sectional view illustrating a semiconductor package in accordance with example implementations.

Referring to FIG. 1, the semiconductor package may include a package substrate 110, a semiconductor chip 210, a die attach film (DAF) 140, a bonding wire 150, a molding member 160, a conductive connection member 170, a bending prevention structure 335 and an electromagnetic-wave shielding structure 370.

FIG. 1 shows that the semiconductor package includes a single semiconductor chip 210 on the package substrate 110, however, the implementations of the disclosure are not limited thereto, and the semiconductor package may include a plurality of semiconductor chips 210 stacked in the vertical direction. In this case, the semiconductor package may be a multi-chip package (MCP) including the same type of semiconductor chips 210 or different types of semiconductor chips 210. Alternatively, the semiconductor package may be a system in package (SIP) in which a plurality of semiconductor chips 210 are stacked or arranged within a single package to function as a single, independent system.

The package substrate 110 may include first and second surfaces 112 and 114 opposite to each other in the vertical direction.

The package substrate 110 may be, e.g., a printed circuit board (PCB). The PCB may be a multiple-layered circuit board including various types of circuit patterns, e.g., transistors, wirings, vias, contact plugs, conductive pads, etc. In example implementations, the circuit patterns may include a first substrate pad 120 adjacent to the first surface 112 of the package substrate 110 and a second substrate pad 130 adjacent to the second surface 114 of the package substrate 110.

The first substrate pad 120 may transmit electrical signals to the semiconductor chips 210 on the package substrate 110, and may function as a bonding pad such as a bonding finger. The second substrate pad 130 may transmit electrical signals to a module substrate, and may function as an external connection pad.

The conductive connection member 170 may contact a lower surface of the second substrate pad 130, and may include, e.g., a conductive bump or a conductive ball.

Each of the first and second substrate pads 120 and 130 may include a metal, e.g., copper, aluminum, nickel, etc., and the conductive connection member 170 may include, e.g., solder that is an alloy of tin, silver, copper, lead, etc.

The semiconductor chip 210 may include first and second surfaces 212 and 214 opposite to each other in the vertical direction. The semiconductor chip 210 may include, e.g., a substrate, first and second insulating interlayers stacked on the substrate in the vertical direction, a circuit device on the substrate and covered by the first insulating interlayer, and a wiring structure in the second insulating interlayer and electrically connected to the circuit device.

The substrate may include a semiconductor material, e.g., silicon, germanium, silicon-germanium, etc., or a III-V group compound semiconductor, such as gallium phosphide (GaP), gallium arsenide (GaAs), or gallium antimonide (GaSb).

The circuit device may include a logic device, a volatile memory device, e.g., a DRAM device, an SRAM device, etc., or a non-volatile memory device, e.g., a flash memory device, an EEPROM device, etc.

The wiring structure may include, e.g., wirings, vias, contact plugs, etc., and may include a chip pad 220 adjacent to the first surface 212 of the semiconductor chip 210. In example implementations, a plurality of chip pads 220 may be spaced apart from each other in the horizontal direction in the semiconductor chip 210.

The semiconductor chip 210 may be bonded to the first surface 112 of the package substrate 110 through the DAF 140 attached to the second surface 214 of the semiconductor chip 210.

The bonding wire 150 may contact the first substrate pad 120 of the package substrate 110 and the chip pad 220 of the semiconductor chip 210 and may electrically connect the first substrate pad 120 and the chip pad 220 to each other. The bonding wire 150 may include a metal, e.g., copper, aluminum, tungsten, nickel, molybdenum, gold, silver, chromium, tin, titanium, etc.

The molding member 160 may be disposed on the first surface 112 of the package substrate 110, and may cover the semiconductor chip 210, the DAF 140 and the bonding wire 150. The molding member 160 may include, e.g., epoxy molding compound (EMC).

In example implementations, the bending prevention structure 335 may contact an upper surface of the molding member 160, and may include first and second bending prevention patterns 315 and 325 alternately stacked in the vertical direction. FIG. 1 shows that the bending prevention structure 335 includes three first bending prevention patterns 315 and three second bending prevention patterns 325, however, the implementations of the disclosure are not limited thereto.

In example implementations, the first bending prevention pattern 315 may include a material having an electrical conductivity lower than an electrical conductivity of the second bending prevention pattern 325. That is, the first bending prevention pattern 315 may include a first conductive material having a first electrical conductivity, and the second bending prevention pattern 325 may include a second conductive material having a second electrical conductivity greater than the first electrical conductivity. For example, the first bending prevention pattern 315 may include a metal such as stainless steel, titanium, etc., and the second bending prevention pattern 325 may include a metal such as gold, silver, copper, etc.

In some example implementations, the first and second bending prevention patterns 315 and 325 may have substantially the same thickness. Alternatively, the first and second bending prevention patterns 315 and 325 may have different thicknesses from each other.

In some example implementations, a plurality of first bending prevention patterns 315 included in the bending prevention structure 335 may have substantially the same thickness. Alternatively, the plurality of first bending prevention patterns 315 included in the bending prevention structure 335 may have different thicknesses from each other.

Likewise, a plurality of second bending prevention patterns 325 included in the bending prevention structure 335 may have substantially the same thickness, or different thicknesses from each other.

Each of the first and second bending prevention patterns 315 and 325 may have a thickness of about 0.1um to about 0.4um.

In example implementations, the electromagnetic-wave shielding structure 370 may be disposed on an upper surface and a sidewall of the bending prevention structure 335, a sidewall of the molding member 160 and a sidewall of the package substrate 110, and may include an adhesion layer 340, a shielding layer 350 and an anti-oxidation layer 360 sequentially stacked. A thicknesses of a portion of each of the adhesion layer 340, the shielding layer 350 and the anti-oxidation layer 360 on the upper surface of the bending prevention structure 335 may be greater than thicknesses of portions of each of the adhesion layer 340, the shielding layer 350 and the anti-oxidation layer 360 on the sidewall of the bending prevention structure 335, the sidewall of the molding member 160 and the sidewall of the package substrate 110.

In example implementations, each of the adhesion layer 340 and the anti-oxidation layer 360 may include a material having an electrical conductivity less than an electrical conductivity of the shielding layer 350. For example, each of the adhesion layer 340 and the anti-oxidation layer 360 may include a metal such as stainless steel, titanium, etc., and the shielding layer 350 may include a metal such as gold, silver, copper, etc. Thus, in some example implementations, each of the adhesion layer 340 and the anti-oxidation layer 360 may include a material substantially the same as a material of the first bending prevention pattern 315, and the shielding layer 350 may include a material substantially the same as a material of the second bending prevention pattern 325.

In some example implementations, the adhesion layer 340, the shielding layer 350 and the anti-oxidation layer 360 may have substantially the same thickness. Alternatively, the adhesion layer 340, the shielding layer 350 and the anti-oxidation layer 360 may have different thicknesses from each other. Alternatively, the adhesion layer 340 and the anti-oxidation layer 360 may have substantially the same thickness, while the shielding layer 350 may have a thickness different from the thickness of the adhesion layer 340 and the anti-oxidation layer 360.

In some example implementations, the adhesion layer 340 and the anti-oxidation layer 360 included in the electromagnetic-wave shielding structure 370 may have a thickness substantially the same as a thickness of the first bending prevention pattern 315 included in the bending prevention structure 335, and the shielding layer 350 included in the electromagnetic-wave shielding structure 370 may have a thickness substantially the same as a thickness of the second bending prevention pattern 325 included in the bending prevention structure 335. Alternatively, each of the adhesion layer 340 and the anti-oxidation layer 360 may have a thickness different from a thickness of the first bending prevention pattern 315, and the shielding layer 350 may have a thickness different from a thickness of the second bending prevention pattern 325.

Each of the adhesion layer 340, the shielding layer 350 and the anti-oxidation layer 360 may have a thickness of about 0.1um to about 0.4um.

The bending prevention structure 335 may be disposed on the upper surface of the molding member 160, and may hinder the semiconductor package from bending due to external impacts. The bending prevention structure 335 may include the first bending prevention patterns 315 and the second bending prevention patterns 325 stacked in the vertical direction, and may have a stiffness greater than a stiffness of a bending prevention structure including only a single bending prevention pattern so as to effectively hinder the semiconductor package from bending.

According to experiment results, when the bending prevention structure 335 on the upper surface of the molding member 160 includes three patterns having a total thickness of about 6.3um, a stiffness of the bending prevention structure 335 was improved by about 1.9% compared to when no bending prevention structure 335 was positioned. Additionally, when the bending prevention structure 335 on the upper surface of the molding member 160 includes nine patterns having the same total thickness, a stiffness of the bending prevention structure 335 was improved by about 4.3% compared to when no bending prevention structure 335 was positioned.

That is, the bending prevention structure 335 may provide improved stiffness when the bending prevention structure 335 includes a greater number of patterns, even if the total thickness remains the same. Thus, the bending prevention structure 335 may include a large number of the first and second bending prevention patterns 315 and 325 stacked in the vertical direction, so that the warping of the semiconductor package may be effectively prevented.

The adhesion layer 340 included in the electromagnetic-wave shielding structure 370 may contact and be bonded to the upper surface and the sidewall of the bending prevention structure 335, the sidewall of the molding member 160 and the sidewall of the package substrate 110, the shielding layer 350 may shield the semiconductor package from external electromagnetic-waves, and the anti-oxidation layer 360 may hinder oxidation of the shielding layer 350.

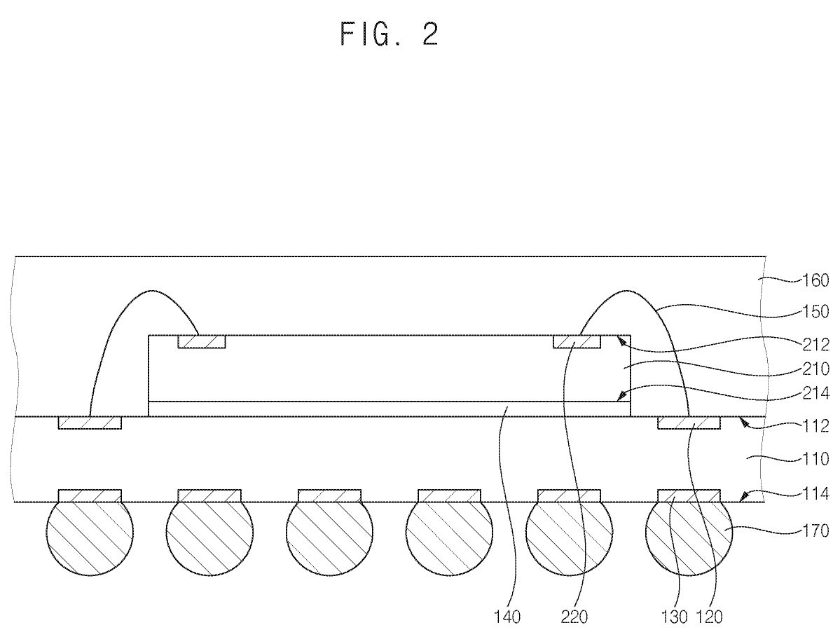

FIGS. 2 to 4 are cross-sectional views illustrating a method of manufacturing a semiconductor package in accordance with example implementations.

Referring to FIG. 2, a semiconductor chip 210 may be bonded to a first surface 112 of a package substrate 110 including the first surface 112 and a second surface 114 opposite to each other in the vertical direction through, e.g., a die attach film (DAF).

The package substrate 110 may be, e.g., a PCB, which may be a multiple-layered circuit board including various types of circuit patterns. In example implementations, the circuit patterns may include a first substrate pad 120 adjacent to the first surface 112 of the package substrate 110 and a second substrate pad 130 adjacent to the second surface 114 of the package substrate 110. A plurality of first substrate pads 120 may be spaced apart from each other in the horizontal direction, and a plurality of second substrate pads 130 may be spaced apart from each other in the horizontal direction.

In example implementations, the package substrate 110 may include a plurality of chip regions spaced apart from each other in the horizontal direction, and FIG. 2 shows a single chip region among the plurality of chip regions.

The semiconductor chip 210 may be disposed on each of the plurality of chip regions of the package substrate 110. The semiconductor chip 210 may include first and second surfaces 212 and 214 opposite to each other in the vertical direction, and may include a chip pad 220 adjacent to the first surface 212 thereof.

A wire bonding process may be performed so that a bonding wire 150 may contact the first substrate pad 120 of the package substrate 110 and the chip pad 220 of the semiconductor chip 210, and thus the first substrate pad 120 and the chip pad 220 may be electrically connected to each other.

A molding member 160 may be formed on the package substrate 110 to cover the semiconductor chip 210, the DAF 140 and the bonding wire 150, and a conductive connection member 170 may be formed on the second surface 114 of the package substrate 110 to contact the second substrate pad 130.

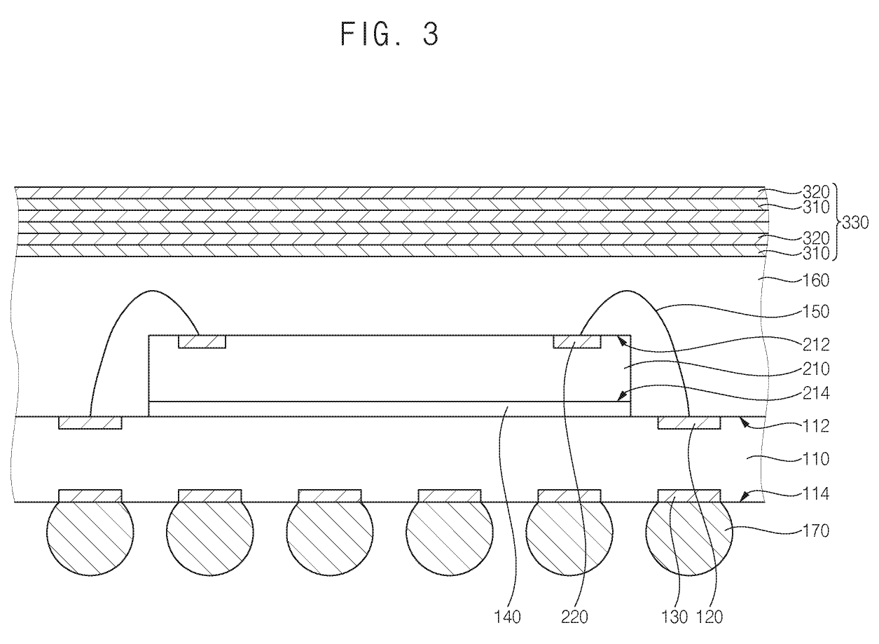

Referring to FIG. 3, a first sputtering process may be performed on an upper surface of the molding member 160 to form a bending prevention layer structure 330.

In example implementations, the bending prevention layer structure 330 may include first and second bending prevention layers 310 and 320 alternately stacked in the vertical direction. FIG. 3 shows three first bending prevention layers 310 and three second bending prevention layers 320, however, the implementations of the disclosure are not necessarily limited thereto.

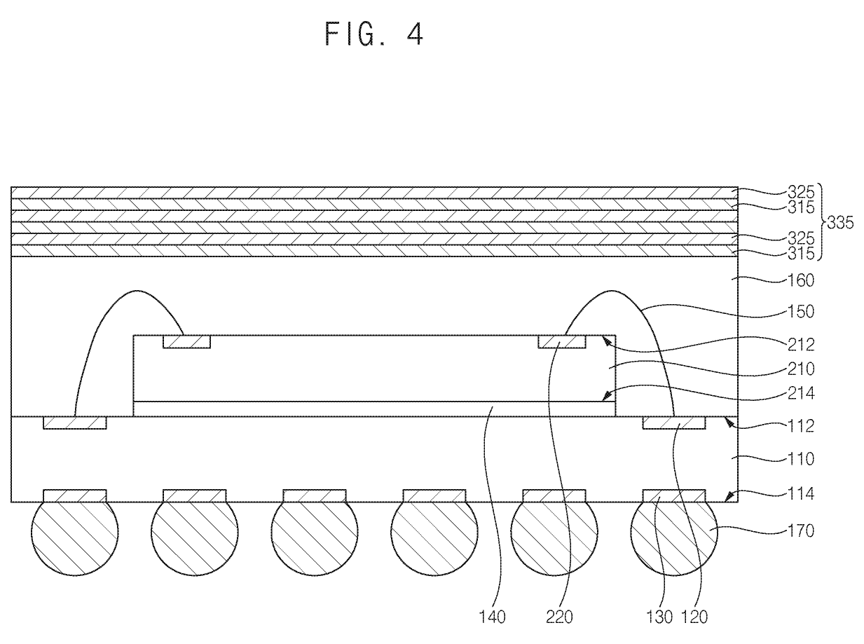

Referring to FIG. 4, for example, a sawing process may be performed so that each of the package substrate 110 and the molding member 160 may be divided into a plurality of parts.

In example implementations, by the sawing process, the package substrate 110 may be divided into a plurality of chip regions, and the DAF 140, the semiconductor chip 210, the bonding wire 150 and the molding member 160 may be disposed on each of the chip regions of the package substrate 110.

Additionally, the bending prevention layer structure 330 may be divided into bending prevention structures 335, and each of the bending prevention structures 335 may be disposed on the upper surface of the molding member 160 on each of the chip regions of the package substrate 110. Each of the bending prevention structures 335 may include first and second bending prevention patterns 315 and 325 alternately stacked in the vertical direction.

Hereinafter, each of the package substrates 110, and the DAF 140, the semiconductor chip 210, the bonding wire 150, the molding member 160 and the bending prevention structure 335 disposed on each of the package substrates 110 altogether may be referred to as a preliminary semiconductor package.

Referring to FIG. 1, for example, a second sputtering process may be performed an electromagnetic-wave shielding structure 370 on an upper surface and a sidewall of the preliminary semiconductor package.

In example implementations, the electromagnetic-wave shielding structure 370 may be formed on an upper surface and a sidewall of the bending prevention structure 335, a sidewall of the molding member 160 and a sidewall of the package substrate 110, and may include an adhesion layer 340, a shielding layer 350 and an anti-oxidation layer 360 sequentially stacked. Due to characteristics of the second sputtering process, a thickness of a portion of each of the adhesion layer 340, the shielding layer 350 and the anti-oxidation layer 360 on the upper surface of the preliminary semiconductor package, that is, the upper surface of the bending prevention structure 335 may be greater than a thickness of a portion of each of the adhesion layer 340, the shielding layer 350 and the anti-oxidation layer 360 on the sidewall of the preliminary semiconductor package, that is, the sidewalls of the bending prevention structure 335, the molding member 160 and the package substrate 110.

By the above processes, the semiconductor package may be manufactured.

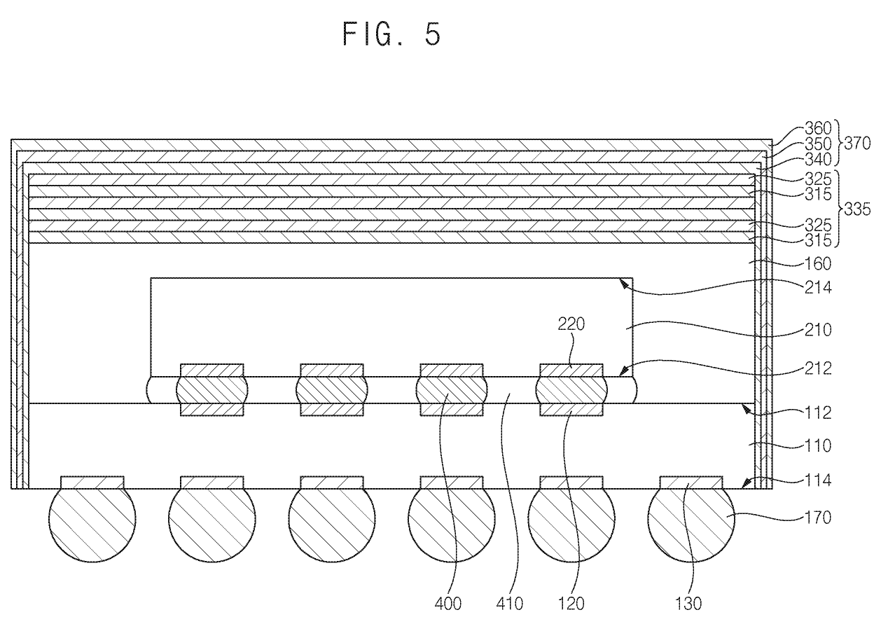

FIG. 5 is a cross-sectional view illustrating a semiconductor package in accordance with example implementations, which may correspond to FIG. 1.

This semiconductor package may be substantially the same as that of FIG. 1, except a process of electrical connection between the package substrate and the semiconductor chip, and thus repeated explanations are omitted herein.

Referring to FIG. 5, the semiconductor chip 210 may be bonded to the package substrate 110 by a flip chip bonding process.

That is, the semiconductor chip 210 illustrated with reference to FIG. 1 may be electrically connected to the package substrate 110 by a wire bonding process using the bonding wire 150, while the semiconductor chip 210 illustrated with reference to FIG. 5 may be electrically connected to the package substrate 110 through the conductive connection member 400 with the first surface 212 of the semiconductor chip 210 facing downwardly.

In example implementations, the conductive connection member 400 may contact a lower surface of the chip pad 220 of the semiconductor chip 210 and an upper surface of the first substrate pad 120 of the package substrate 110. The conductive connection member 400 may include, e.g., a conductive bump or a conductive ball, which may include, e.g., solder.

A bonding layer 410, e.g., a non-conductive film (NCF) or an underfill member may be disposed between the first surface 112 of the package substrate 110 and the first surface 212 of the semiconductor chip 210.

The foregoing is illustrative of example implementations and is not to be construed as limiting thereof. Although a few example implementations have been described, those skilled in the art will readily appreciate that many modifications are possible in example implementations without materially departing from the novel teachings and advantages of the present invention. Accordingly, all such modifications are intended to be included within the scope of example implementations as defined in the claims.

### In addition to the implementations described above, the following implementations are also innovative:

Implementation 1 is a method of manufacturing a semiconductor package, the method comprising:

disposing a semiconductor chip on a package substrate;

forming a molding member on the package substrate to cover the semiconductor chip;

forming a bending prevention layer structure on the molding member;

performing a sawing process on the package substrate and the molding member to form a plurality of preliminary semiconductor packages; and

forming an electromagnetic-wave shielding structure on an upper surface and a sidewall of each preliminary semiconductor package of the plurality of preliminary semiconductor packages.

Implementation 2 is the method according to implementation 1, wherein forming the bending prevention layer structure on the molding member includes:

alternately stacking first and second bending prevention layers on the molding member.

Implementation 3 is the method according to implementation 2, wherein the first bending prevention layer includes a first material and the second bending prevention layer includes a second conductive material, the first conductive material and the second conductive material being different from each other.

Implementation 4 is the method according to implementation 3, wherein the first conductive material has a first electrical conductivity, and the second conductive material has a second electrical conductivity.

Implementation 5 is the method according to implementation 4, wherein the first conductive material includes stainless steel or titanium, and the second conductive material includes gold, silver or copper.

Implementation 6 is the method according to implementation 2, wherein the first bending prevention layer and the second bending prevention layer have different thicknesses from each other.

Implementation 7 is the method according to implementation 1, wherein forming the electromagnetic-wave shielding structure includes:

sequentially stacking an adhesion layer, a shielding layer and an anti-oxidation layer on the upper surface and the sidewall of each preliminary semiconductor package of the plurality of preliminary semiconductor packages.

Implementation 8 is the method according to implementation 7, wherein each of the adhesion layer and the anti-oxidation layer includes a first conductive material, and the shielding layer includes a second conductive material.

Implementation 9 is the method according to implementation 8, wherein the first conductive material includes stainless steel or titanium, and the second conductive material includes gold, silver or copper.

Implementation 10 is the method according to implementation 7, wherein the adhesion layer and the anti-oxidation layer have the same thickness, and the shielding layer has a thickness different from a thickness of the adhesion layer and the anti-oxidation layer.

What is claimed is:

1. A semiconductor package comprising:
a package substrate;
a semiconductor chip on the package substrate;
a molding member on the package substrate and covering the semiconductor chip;
a bending prevention structure on an upper surface of the molding member, the bending prevention structure including bending prevention patterns stacked in a vertical direction substantially perpendicular to an upper surface of the package substrate; and
an electromagnetic-wave shielding structure on an upper surface and a sidewall of the bending prevention structure, a sidewall of the molding member and a sidewall of the package substrate.

2. The semiconductor package according to claim 1, wherein the bending prevention patterns include at least one first bending prevention pattern and at least one second bending prevention pattern, the at least one first bending prevention pattern including a first conductive material and the at least one second bending prevention pattern including a second conductive material that is different from the first conductive material.

3. The semiconductor package according to claim 2, wherein the at least one first bending prevention pattern comprises a plurality of first bending prevention patterns and the at least one second bending prevention pattern comprises a plurality of second bending prevention patterns,
and wherein the plurality of first bending prevention patterns and the plurality of second bending prevention patterns are alternately stacked in the vertical direction.

4. The semiconductor package according to claim 3, wherein the first bending prevention pattern contacts the upper surface of the molding member.

5. The semiconductor package according to claim 2, wherein an electrical conductivity of the first conductive material is lower than an electrical conductivity of the second conductive material.

6. The semiconductor package according to claim 5, wherein the first conductive material includes stainless steel or titanium, and the second conductive material includes gold, silver or copper.

7. The semiconductor package according to claim 2, wherein the first bending prevention pattern and the second bending prevention pattern have different thicknesses from each other.

8. The semiconductor package according to claim 2, wherein the first bending prevention pattern and the second bending prevention pattern have the same thickness.

9. The semiconductor package according to claim 2, wherein the at least one first bending prevention pattern comprises a plurality of first bending prevention patterns and the at least one second bending prevention pattern comprises a plurality of second bending prevention patterns.

10. The semiconductor package according to claim 1, wherein the electromagnetic-wave shielding structure includes an adhesion layer, a shielding layer and an anti-oxidation layer sequentially stacked.

11. The semiconductor package according to claim 10, wherein each of the adhesion layer and the anti-oxidation layer includes a first conductive material having a first electrical conductivity, and the shielding layer includes a second conductive material having a second electrical conductivity greater than the first electrical conductivity.

12. The semiconductor package according to claim 11, wherein the adhesion layer contacts the upper surface and the sidewall of the bending prevention structure, the sidewall of the molding member and the sidewall of the package substrate.

13. The semiconductor package according to claim 11, wherein the first conductive material includes stainless steel or titanium, and the second conductive material includes gold, silver or copper.

14. A semiconductor package comprising:
a package substrate;
a semiconductor chip on the package substrate;
a molding member on the package substrate and covering the semiconductor chip;
a bending prevention structure on an upper surface of the molding member, the bending prevention structure including first and second bending prevention patterns alternately stacked in a vertical direction substantially perpendicular to an upper surface of the package substrate; and
an electromagnetic-wave shielding structure on an upper surface and a sidewall of the bending prevention structure, a sidewall of the molding member and a sidewall of the package substrate,
wherein the first bending prevention pattern includes a first conductive material having a first electrical conductivity, and the second bending prevention pattern includes a second conductive material having a second electrical conductivity greater than the first electrical conductivity.

15. The semiconductor package according to claim 14, wherein the first conductive material includes stainless steel or titanium, and the second conductive material includes gold, silver or copper.

16. The semiconductor package according to claim 14, wherein the first bending prevention pattern and the second bending prevention pattern have different thicknesses from each other.

17. The semiconductor package according to claim 14, wherein the electromagnetic-wave shielding structure includes an adhesion layer, a shielding layer and an anti-oxidation layer sequentially stacked.

18. The semiconductor package according to claim 17, wherein each of the adhesion layer and the anti-oxidation layer includes the first conductive material, and the shielding layer includes the second conductive material.

19. A semiconductor package comprising:
a package substrate;
a semiconductor chip on the package substrate;
a bonding wire electrically connecting the package substrate and the semiconductor chip;
a molding member on the package substrate and covering the semiconductor chip and the bonding wire;
a bending prevention structure on an upper surface of the molding member, the bending prevention structure including first and second bending prevention patterns alternately stacked in a vertical direction substantially perpendicular to an upper surface of the package substrate;
an electromagnetic-wave shielding structure on an upper surface and a sidewall of the bending prevention structure, a sidewall of the molding member and a sidewall of the package substrate, the electromagnetic-wave shielding structure including an adhesion layer, a shielding layer and an anti-oxidation layer sequentially stacked; and
an external connection pad on a lower surface of the package substrate.

20. The semiconductor package according to claim 19, wherein each of the first bending prevention pattern, the adhesion layer and the anti-oxidation layer includes stainless steel or titanium, and each of the second bending prevention pattern and the shielding layer includes gold, silver or copper.
